(19) United States
(12) Patent Application Publication
(10) Pub. No.: US 2025/0005368 A1
(43) Pub. Date: Jan. 2, 2025

(54) REINFORCED LEARNING FOR QUANTUM DESIGN

(71) Applicant: INTERNATIONAL BUSINESS MACHINES CORPORATION, Armonk, NY (US)

(72) Inventors: Juan Cruz Benito, Salamanca (ES); Zlatko Kristev Minev, White Plains, NY (US); Francisco Jose Martin Fernandez, Ridgefield, CT (US); Ismael Faro Sertage, Chappaqua, NY (US)

(21) Appl. No.: 18/463,240

(22) Filed: Sep. 7, 2023

(30) Foreign Application Priority Data
Jun. 27, 2023 (EP) 23382657.7

(51) Int. Cl. G06N 3/092; G06F 30/31; G06N 3/045

(52) U.S. Cl. CPC G06N 3/092; G06F 30/31; G06N 3/045

(57) ABSTRACT

A computer-implemented process for generating a policy for design of quantum devices using a quantum hardware design kit including instructions and parameters associated with the instructions includes the following operations. An environment for a reinforcement learning architecture that includes a neural network as at least part of an agent is defined. A policy is generated by training the neural network using the environment. The defining the environment includes: defining actions of the neural network from a set of the instructions and parameters combinations associated with the quantum hardware design kit; and defining a reward function for generation of the policy.

### BACKGROUND

The present invention relates to machine learning, and more specifically, to training a neural network model for designing quantum systems using reinforcement learning.

Quantum computing is a rapidly-emerging technology that harnesses the laws of quantum mechanics to solve a wide variety of problems including those deemed too complex for classical computers. Physical hardware systems employing quantum computing (hereinafter referred to as quantum computers or quantum devices) have recently been developed. For example, IBM Corporation provides a quantum device that includes a 27 qubit Falcon process, a 65 qubit Hummingbird processor, and a 127 qubit Eagle processor. Although this particular quantum device employs superconducting qubits, other types of quantum technologies include quantum dot qubits, trapped ion qubits, photonic qubits, defect-based qubits, topological qubits, and nuclear magnetic resonance (NMR). As also used herein, a quantum device, is any device that uses an explicit quantum property (e.g., spin of a quantum particular) for its functionality. As also used herein a quantum program is a discrete piece of source code, using any language, that include instructions to run on a quantum device.

Although traditional electronic design automation (EDA) tools have long been used traditional circuit decision, quantum computers are unlike conventional semiconductor-based microprocessors. For example, in a superconductor-based quantum device, the quantum bits can be substantially larger than transistors and require complex superconducting circuitry. To support the use of these quantum devices, quantum (EDA) tools have been provided, and Qiskit Metal is an example of such a EDA tool. Such quantum EDA tools provide a library of predefined quantum components, such as transmon qubits and coplanar resonators, which a designer can select and customize the parameters for. These quantum EDA tools can also automate the quantum electrodynamics modeling of quantum devices to predict their performance and parameters, such as qubit frequencies, anharmonicities, non-linear couplings, and dissipation. For example, the design of a quantum device might start with the design of a physical layout followed by an electromagnetic analysis and a quantum Hamiltonian analysis used for the determination of a qubit Hilbert space. In short, quantum EDA tools can provide for the design, modeling, and analysis of quantum devices.

### SUMMARY

A computer-implemented process for generating a policy for design of quantum devices using a quantum hardware design kit including instructions and parameters associated with the instructions includes the following operations. An environment for a reinforcement learning architecture that includes a neural network as at least part of an agent is defined. The policy is generated by training the neural network using the environment. The defining the environment includes: defining actions of the neural network from a set of the instructions and parameters combinations associated with the quantum hardware design kit; and defining a reward function for generation of the policy. The policy can be used to improve the process of designing quantum devices. For example, a user can submit a predefined design of a quantum device, and the policy can be used to discover new parameter combinations that enhance the behavior of the quantum device. As another example, a user can request discovery of new hardware designs using the policy without providing a template from which to work.

In other aspects of the process, the defining the environment includes receiving quantum device architecture, and the reward function is configured to optimize the parameters for the quantum device architecture. The reward function can also be configured to reward completion of a design of a quantum device. Additionally, the reward function can be changed during the generating the policy. A second neural network may be configured to generate values associated with the reward function. The environment can include, separate from the quantum hardware design kit, a third-party library of predefined quantum components. Also, the defining the environment includes defining physical constraints of a quantum device.

A computer hardware system for generating a policy for design of quantum devices using a quantum hardware design kit including instructions and parameters associated with the instructions includes a hardware processor configured to perform the following operations. An environment for a reinforcement learning architecture that includes a neural network as at least part of an agent is defined. The policy is generated by training the neural network using the environment. The defining the environment includes: defining actions of the neural network from a set of the instructions and parameters combinations associated with the quantum hardware design kit; and defining a reward function for generation of the policy. The policy can be used to improve the process of designing quantum devices. For example, a user can submit a predefined design of a quantum device, and the policy can be used to discover new parameter combinations that enhance the behavior of the quantum device. As another example, a user can request discovery of new hardware designs using the policy without providing a template from which to work.

In other aspects of the hardware system, the defining the environment includes receiving quantum device architecture, and the reward function is configured to optimize the parameters for the quantum device architecture. The reward function can also be configured to reward completion of a design of a quantum device. Additionally, the reward function can be changed during the generating the policy. A second neural network may be configured to generate values associated with the reward function. The environment can include, separate from the quantum hardware design kit, a third-party library of predefined quantum components. Also, the defining the environment includes defining physical constraints of a quantum device.

A computer program product includes a computer readable storage medium having stored therein program code for generating a policy for design of quantum devices using a quantum hardware design kit including instructions and parameters associated with the instructions includes the following operations is disclosed. The program code, which when executed by computer hardware system, cause the computer hardware system to perform the following. An environment for a reinforcement learning architecture that includes a neural network as at least part of an agent is defined. The policy is generated by training the neural network using the environment. The defining the environment includes: defining actions of the neural network from a set of the instructions and parameters combinations associated with the quantum hardware design kit; and defining a reward function for generation of the policy. The policy can be used to improve the process of designing quantum devices. For example, a user can submit a predefined design of a quantum device, and the policy can be used to discover new parameter combinations that enhance the behavior of the quantum device. As another example, a user can request discovery of new hardware designs using the policy without providing a template from which to work.

In other aspects of the computer program product, the defining the environment includes receiving quantum device architecture, and the reward function is configured to optimize the parameters for the quantum device architecture. The reward function can also be configured to reward completion of a design of a quantum device. Additionally, the reward function can be changed during the generating the policy. A second neural network may be configured to generate values associated with the reward function. The environment can include, separate from the quantum hardware design kit, a third-party library of predefined quantum components. Also, the defining the environment includes defining physical constraints of a quantum device.

This Summary section is provided merely to introduce certain concepts and not to identify any key or essential features of the claimed subject matter. Other features of the inventive arrangements will be apparent from the accompanying drawings and from the following detailed description.

### BRIEF DESCRIPTION OF THE DRAWINGS

FIG. 1 is a flowchart of a typical reinforcement learning (RL) approach.

FIGS. 2A and 2B are block diagrams respectively schematically illustrating a reinforcement learning (RL) architecture and a deep Q-learning (DQN) architecture.

FIG. 3 is a block diagram illustrating an architecture of an example quantum hardware design system according to at least one embodiment of the present invention.

FIG. 4 illustrates an example method using the architecture of FIG. 3 according to at least one embodiment of the present invention.

FIG. 5 is a block diagram illustrating an example of computer environment for implementing the methodology of FIGS. 1 and 4.

### DETAILED DESCRIPTION

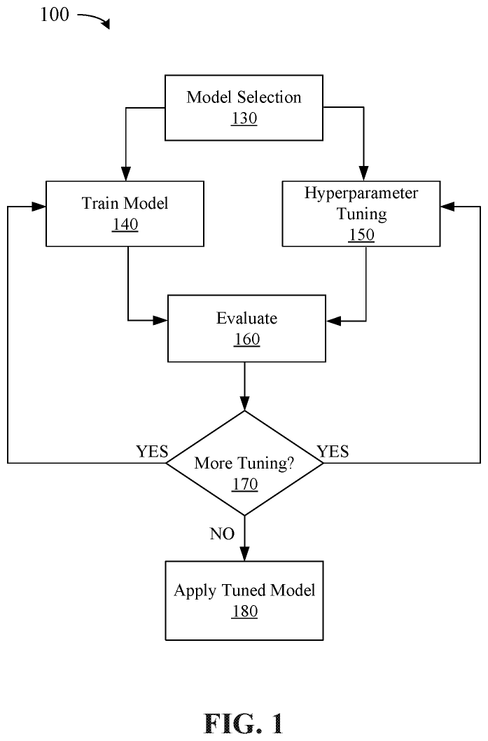

With reference to FIG. 1, a generic process 100 for machine learning is disclosed. In 130, the model to be trained is selected. There are a number of known models that can be used with machine learning. A non-exclusive list of these models includes linear regression, Deep Neural Networks (DNN), logistic regression, and decision trees. Depending upon the type of solution needed for a particular application, one or more models may be better suited.

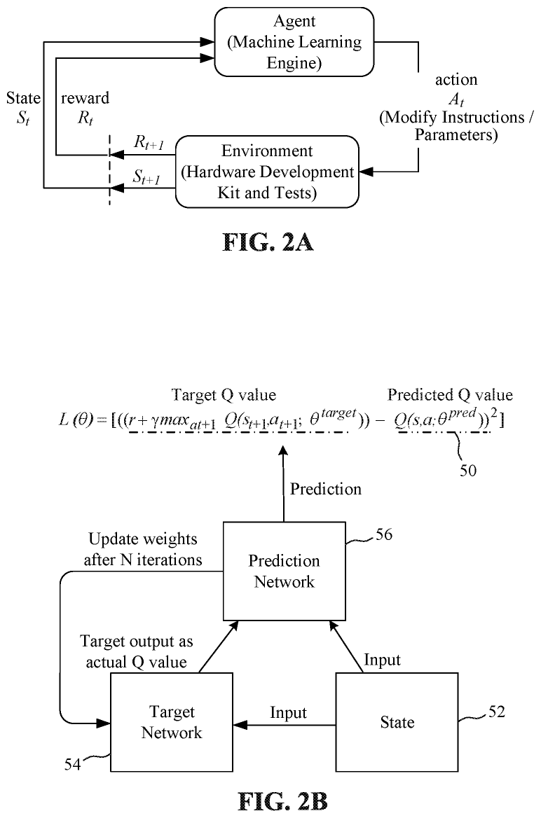

In 140, the parameters of the model are tuned. There are many different types of known techniques used to train a model. Some of these techniques are discussed in further detail with regard to FIGS. 2A-2B. In 150, hyperparameters can be tuned. Hyperparameters are variables that govern the training process itself and differ from input data (i.e., the training data) and the parameters of the model. Examples of hyperparameters include, for example, the number of hidden layers in a DNN between the input layer and the output layer. Other examples include number of training steps, learning rate, and initialization values. In certain instances, the validation dataset can be used as part of this tuning process. Although illustrated as being separate from the tuning of the parameters of model in 150, the tuning of the hyperparameters can be performed in parallel with or in series with the tuning of the parameters of the model in 140.

In 160, the parameters of the model and the hyperparameters are evaluated. This typically involves using some metric or combination of metrics to generate an objective descriptor of the performance of the model. The evaluation typically uses data that has yet to be seen by the model (e.g., new interactions with the environment). The operations of 140-160 continue until a determination, in 170, that no additional tuning is to be performed. In 180, the tuned model can then be applied to real-world data.

FIGS. 2A and 2B are block diagrams respectively illustrating a reinforcement learning (RL) architecture and a deep Q-learning (DQN) architecture for training a model. Machine learning paradigms include supervised learning (SL), unsupervised learning (UL), and reinforcement learning (RL). RL differs from SL by not requiring labeled input/output pairs and not requiring sub-optimal actions to be explicitly corrected. FIG. 2A schematically illustrates a generic RL approach. In describing RL, the following terms are oftentimes used. The “environment” refers to the world in which the agent operates. The “State” (Sₜ) refers to a current situation of the agent. Each State (Sₜ) may have one or more dimensions that describe the State. The “reward” (Rₜ) is feedback from the environment (also illustrated as “r” in FIG. 2B), which is used to evaluate actions (Aₜ) taken by the agent.

A reward function, which is part of the environment, generates the reward (Rₜ), and the reward function reflects the desired goal of the model being trained. The “policy” (π) is a methodology by which to map the State (Sₜ) of the agent to certain actions (Aₜ). Formally, the policy π(s) is defined as the suggested action (or a probably distribution of actions) that the agent should take for every possible state s∈S. The “value” is a future reward received by an agent by taking an action (Aₜ) in a particular State (Sₜ). Ultimately, the goal of the agent is to generate actions (Aₜ) that maximize the reward function.

Examples of RL algorithms that may be used include Markov decision process (MDP), Monte Carlo methods, temporal difference learning, Q-learning, Deep Q Networks (DQN), State-Action-Reward-State-Action (SARSA), a distributed cluster-based multi-agent bidding solution (DCMAB), and the like. FIG. 2B illustrates one example of the operation of a DQN model. DQN is a combination of deep learning (i.e., neural network based) and reinforcement learning. Deep learning is another subfield of machine learning that involves artificial neural networks. An example of a computer system that employs deep learning is IBM's Watson. While the terms “neural network” and “deep learning” are oftentimes used interchangeably, by popular convention, deep learning (e.g., with a DNN), refers to a neural network with more than three layers inclusive of the inputs and the output. A neural network with just two or three layers is considered just a basic neural network.

A neural network can be seen as a universal functional approximator that can be used to replace the Q-table used in Q-learning. In a DQN model, the loss function 50 is represented as a squared error of the target Q value and prediction Q value. Error is minimized by optimizing the weights, θ. In DQN, two separate networks (i.e., target network 54 and prediction network 56 having the same architecture) can be respectively employed to estimate target and prediction Q values based upon state 52. The result from the target model is treated as a ground truth for the prediction network 56. The weights for the prediction network 56 get updated every iteration and the weights of the target network 54 get updated with the prediction network 56 after N iterations.

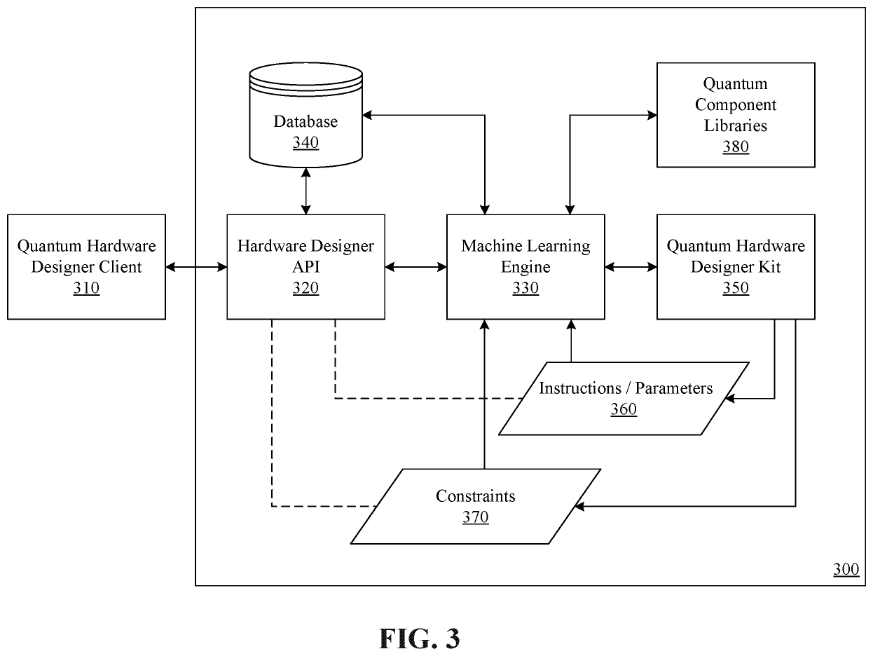

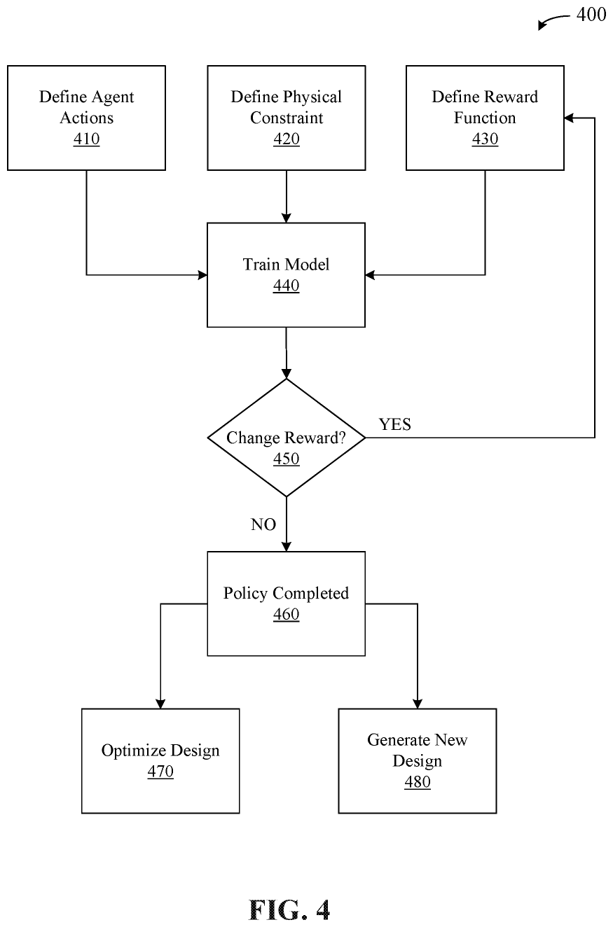

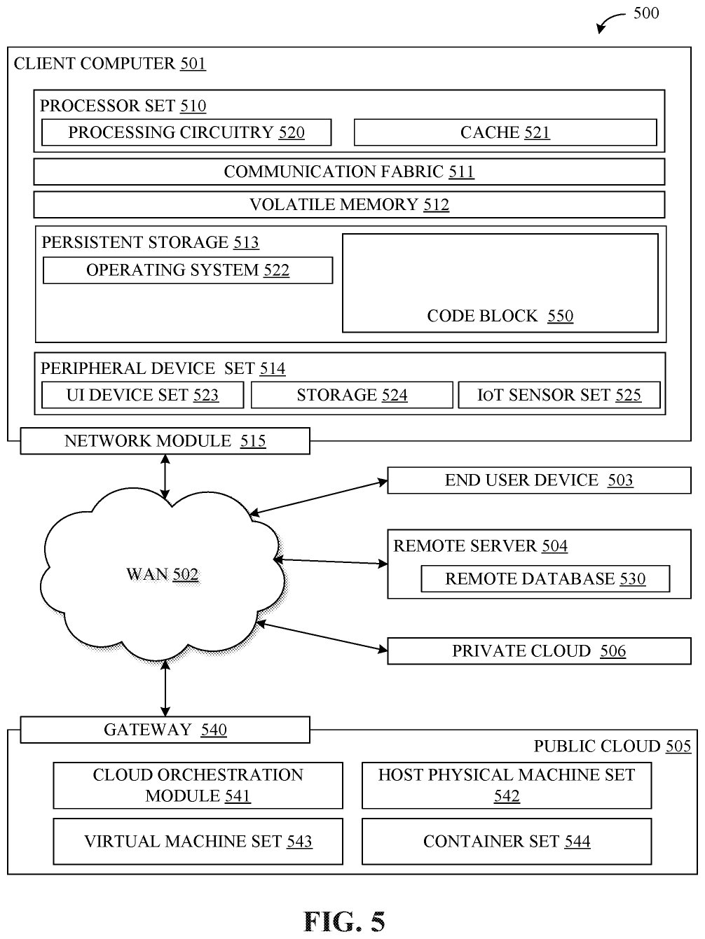

Reference is made to FIGS. 3 and 4, which respectively illustrate a quantum design system 300 and methodology 400 for using a reinforcement learning architecture (as illustrated in FIGS. 2A-B) for designing quantum devices. The proposed quantum design system 300 and methodology 400 improves the process of designing quantum devices by generating a policy that can be used to both generate new quantum device designs and to improve upon current quantum device designs. Although not limited in this manner, the quantum design system 300 includes a hardware designer application programming interface (API) 320 configured to interact with one or more quantum hardware designer clients 310, a machine learning engine 330, database 340, a quantum hardware design kit 350, and one or more third-party, quantum component libraries 380. Although illustrated as being within a single system 300, the individual components 320, 330, 340, 350, 380 of the quantum design system 300 can be distributed over a plurality of computer devices. Additionally, the machine learning engine 330 could be within a standalone computer system (not shown) or located in a cloud computing system such as described in FIG. 5.

As discussed in more detail below, the quantum design system 300 is configured to generate a policy for designing quantum devices using the quantum hardware design kit 350, which includes instructions and parameters 360 associated with the instructions. The reinforcement learning architecture (such as illustrated in FIGS. 2A-B) includes a neural network (e.g., machine learning engine 330) acting as at least part of the agent. The environment of the reinforcement learning architecture is defined by defining actions of the neural network 330 from a set of instructions and parameters combinations 360 associated with the quantum hardware design kit 350 and defining a reward function for training the neural network 330. A policy is generated by training the neural network 330 using the environment.

The quantum hardware designer client 310 and quantum hardware design kit 350 can be an EDA tool, such as Qiskit Metal. For example, the client 310 could be implemented using the front-facing client of Qiskit Metal, and the design kit 350 could be implemented using the back-end portion of Qiskit Metal, which can include, for example, a library of predefined/prebuilt quantum components and the interfaces to use them via code.

The database 340 can store each iteration of the reinforcement learning process, as well as the decisions taken by the agent (i.e., machine learning engine 330), the hardware results, and the testing results from the quantum hardware design kit. The hardware results are related to the hardware designed by the RL algorithm, and the testing results are related to the metrics obtained using that hardware design in a specific set of tests.

The quantum hardware design kit 350 is configured to analyze the results of the action(s) taken by the machine learning engine 330. This analysis can involve determine, for example, if the code is valid, is runnable, and what kind of outputs is produced by the new design. Although not limited to the particular types of analysis described, the quantum hardware design kit 350 can perform any one or combination of Lumped-Oscillator-Model (LOM) analysis, Energy-Participation-Ratio (EPR) analysis, analytic or EPR analysis on a coplanar waveguide (CPW) resonator, and impedance analysis, such as black-box quantization or any other relevant test/analysis existing now or in the future.

Referring to process 400, in 410-430, the environment and the actions taken by the agent (i.e., machine learning engine 330) are defined. Although illustrated as being performed in parallel, any number of operations 410-430 can be performed serially, in parallel, or a combination of both. As discussed above, the “environment” refers to the world in which the agent 330 operates. Consequently, the possible actions taken by the agent 330 are limited by the environment.

In 410, actions to be performed by the agent (i.e., machine learning engine 330) are defined from a set of instructions/parameters 360 capable of being implemented by the environment (i.e., quantum hardware design kit 350). Although not limited in this manner, the client 310 can use the quantum hardware designer client 310 to select, from the quantum hardware design kit 350, the actions to be performed within the quantum hardware design kit 350. These actions include all (or a subset of) of programming code statements 360 (including quantum programming statements) used to design/implement a quantum device. The client 310 can also be used to select, as part of the actions, all (or a subset of) of parameters associated with these programming code statements. By permitting just a subset of parameters to be selected, parameter space can be limited, which can permit hardware designs to be discovered faster. Additionally, the client 310 can be used to set constraints on the dynamic range of these parameters (i.e., how the parameters can be varied) and impose a cost function over the parameter values, which can provide soft enforcement of a physical and practical range of design parameters. Consequently, the improvement of different parameters and/or components can be favored over others.

In 420, physical constraints 370 of the quantum device being modeled by the quantum hardware design kit 350 can be defined. Although not limited in this manner, a user of the client 310 can use the quantum hardware designer client 310 to select, from the quantum hardware design kit 350, physical constraints to be enforced by the quantum hardware design kit 350 in designing the quantum device. These physical constraints can include, for example, frequency collision conditions, location constraints, and material constraints.

In 430, the reward function used to train the model (i.e., neural network/machine learning engine) is selected. As discussed above, the reward function reflects the desired goal of the model being trained. For example, the policy may initially be trained with the goal of discovering new hardware designs. Alternatively, another goal would be to optimize a particular quantum design (e.g., by discovering new parameter combinations). For example, if the goal is to discover new hardware designs, the reward function may be based upon whether agent is able to use the library of predefined quantum components native to the quantum hardware design kit 350 and/or use third party quantum component libraries 380. Additionally, the reward function may be based upon whether the agent is able to complete a qubit design. Alternatively, if the goal is to optimize a particular quantum design, the reward function may be based on an analysis of the design using, for example, one or more of LOM analysis, EPR analysis, analytic or EPR analysis on a CPW resonator, and impedance analysis, such as black-box quantization.

In certain aspects, the exact values for the rewards may be determined using another (e.g., a second) deep learning network (e.g., either part of machine learning engine 330 or separate). Also, a Deep Q Learning algorithm can be used to replace the definition of the Q Table by using a neural network (or multiple neural networks). Consequently, rather than mapping a state-action pair to a q-value, a neural network maps input states to (action, Q-value) pairs.

In 440, the model is trained, for example, using the process discussed above with regard to FIGS. 1 and 2A-B and based upon the definition of the environment described above with regard to operations 410-430. Each iteration of the training, decisions made during the training, hardware results, and testing results can be stored in database 340, which can be accessed by users of the designer client 310 via the hardware designer API 320.

In 450, a determination is made whether to change the reward function. As previously discussed, the reward function reflects the desired goal of the model being trained. As discussed above with regard to operation 430, one goal may be to generate a policy that is capable of optimizing a particular quantum design and another goal may be to generate a policy that is capable of discovering new hardware designs. If the intent is to have a policy that is capable of performing both functions, at one point during the process 400, a determination is made to change the reward function. For example, the policy may initially be trained with the goal of discovering new hardware designs with one reward function and then trained again with a second reward function whose goal is to optimize a particular quantum design (e.g., by discovering new parameter combinations). Once the model has been trained in 440 and either one or more reward functions have been employed, in 460, the policy is completed. As discussed above, the policy π(s) is defined as the suggested action (or a probably distribution of actions) that the agent should take for every possible state s∈S.

Referring to operations 470 and 480, the policy can be used to improve the process of designing quantum devices. For example, in 470, a user can submit, via the designer client 310, a predefined design of a quantum device, and the policy can be used to discover new parameter combinations that enhance the behavior of the quantum device. These characteristics can include, for example, different parts of the hardware design or their working parameters. As another example, in 480, a user can, via the design client 310, request discovery of new hardware designs (e.g., a qubit component) without providing a template from which to work and/or without initial constraints.

As defined herein, the term “responsive to” means responding or reacting readily to an action or event. Thus, if a second action is performed “responsive to” a first action, there is a causal relationship between an occurrence of the first action and an occurrence of the second action, and the term “responsive to” indicates such causal relationship.

As defined herein, the term “real time” means a level of processing responsiveness that a user or system senses as sufficiently immediate for a particular process or determination to be made, or that enables the processor to keep up with some external process.

As defined herein, the term “automatically” means without user intervention.

Referring to FIG. 5, computing environment 500 contains an example of an environment for the execution of at least some of the computer code involved in performing the inventive methods, such as code block 550 for a quantum design system. Computing environment 500 includes, for example, computer 501, wide area network (WAN) 502, end user device (EUD) 503, remote server 504, public cloud 505, and private cloud 506. In certain aspects, computer 501 includes processor set 510 (including processing circuitry 520 and cache 521), communication fabric 511, volatile memory 512, persistent storage 513 (including operating system 522 and method code block 550), peripheral device set 514 (including user interface (UI), device set 523, storage 524, and Internet of Things (IoT) sensor set 525), and network module 515. Remote server 504 includes remote database 530. Public cloud 505 includes gateway 540, cloud orchestration module 541, host physical machine set 542, virtual machine set 543, and container set 544.

Computer 501 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 530. As is well understood in the art of computer technology, and depending upon the technology, performance of a computer-implemented method may be distributed among multiple computers and/or between multiple locations. However, to simplify this presentation of computing environment 500, detailed discussion is focused on a single computer, specifically computer 501. Computer 501 may or may not be located in a cloud, even though it is not shown in a cloud in FIG. 5 except to any extent as may be affirmatively indicated.

Processor set 510 includes one, or more, computer processors of any type now known or to be developed in the future. As defined herein, the term “processor” means at least one hardware circuit (e.g., an integrated circuit) configured to carry out instructions contained in program code. Examples of a processor include, but are not limited to, a central processing unit (CPU), an array processor, a vector processor, a digital signal processor (DSP), a field-programmable gate array (FPGA), a programmable logic array (PLA), an application specific integrated circuit (ASIC), programmable logic circuitry, and a controller. Processing circuitry 520 may be distributed over multiple packages, for example, multiple, coordinated integrated circuit chips. Processing circuitry 520 may implement multiple processor threads and/or multiple processor cores. Cache 521 is memory that is located in the processor chip package(s) and is typically used for data or code that should be available for rapid access by the threads or cores running on processor set 510. Cache memories are typically organized into multiple levels depending upon relative proximity to the processing circuitry. Alternatively, some, or all, of the cache for the processor set may be located “off chip.” In certain computing environments, processor set 510 may be designed for working with qubits and performing quantum computing.

Computer readable program instructions are typically loaded onto computer 501 to cause a series of operational steps to be performed by processor set 510 of computer 501 and thereby effect a computer-implemented method, such that the instructions thus executed will instantiate the methods specified in flowcharts and/or narrative descriptions of computer-implemented methods discussed above in this document (collectively referred to as “the inventive methods”). These computer readable program instructions are stored in various types of computer readable storage media, such as cache 521 and the other storage media discussed below. The program instructions, and associated data, are accessed by processor set 510 to control and direct performance of the inventive methods. In computing environment 500, at least some of the instructions for performing the inventive methods may be stored in code block 550 in persistent storage 513.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Communication fabric 511 is the signal conduction paths that allow the various components of computer 501 to communicate with each other. Typically, this communication fabric 511 is made of switches and electrically conductive paths, such as the switches and electrically conductive paths that make up busses, bridges, physical input/output ports and the like. Other types of signal communication paths may be used for the communication fabric 511. such as fiber optic communication paths and/or wireless communication paths.

Volatile memory 512 is any type of volatile memory now known or to be developed in the future. Examples include dynamic type random access memory (RAM) or static type RAM. Typically, the volatile memory 512 is characterized by random access, but this is not required unless affirmatively indicated. In computer 501, the volatile memory 512 is located in a single package and is internal to computer 501. In addition to alternatively, the volatile memory 512 may be distributed over multiple packages and/or located externally with respect to computer 501.

Persistent storage 513 is any form of non-volatile storage for computers that is now known or to be developed in the future. The non-volatility of the persistent storage 513 means that the stored data is maintained regardless of whether power is being supplied to computer 501 and/or directly to persistent storage 513. Persistent storage 513 may be a read only memory (ROM), but typically at least a portion of the persistent storage 513 allows writing of data, deletion of data and re-writing of data. Some familiar forms of persistent storage 513 include magnetic disks and solid state storage devices. Operating system 522 may take several forms, such as various known proprietary operating systems or open source Portable Operating System Interface type operating systems that employ a kernel. The code included in code block 550 typically includes at least some of the computer code involved in performing the inventive methods.

Peripheral device set 514 includes the set of peripheral devices for computer 501. Data communication connections between the peripheral devices and the other components of computer 501 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet.

In various aspects, UI device set 523 may include components such as a display screen, speaker, microphone, wearable devices (such as goggles and smart watches), keyboard, mouse, printer, touchpad, game controllers, and haptic devices. Storage 524 is external storage, such as an external hard drive, or insertable storage, such as an SD card. Storage 524 may be persistent and/or volatile. In some aspects, storage 524 may take the form of a quantum computing storage device for storing data in the form of qubits. In aspects where computer 501 is required to have a large amount of storage (for example, where computer 501 locally stores and manages a large database) then this storage 524 may be provided by peripheral storage devices designed for storing very large amounts of data, such as a storage area network (SAN) that is shared by multiple, geographically distributed computers. Internet-of-Things (IoT) sensor set 525 is made up of sensors that can be used in IoT applications. For example, one sensor may be a thermometer and another sensor may be a motion detector.

Network module 515 is the collection of computer software, hardware, and firmware that allows computer 501 to communicate with other computers through a Wide Area Network (WAN) 502. Network module 515 may include hardware, such as modems or Wi-Fi signal transceivers, software for packetizing and/or de-packetizing data for communication network transmission, and/or web browser software for communicating data over the internet. In certain aspects, network control functions and network forwarding functions of network module 515 are performed on the same physical hardware device. In other aspects (for example, aspects that utilize software-defined networking (SDN)), the control functions and the forwarding functions of network module 515 are performed on physically separate devices, such that the control functions manage several different network hardware devices. Computer readable program instructions for performing the inventive methods can typically be downloaded to computer 501 from an external computer or external storage device through a network adapter card or network interface included in network module 515.

WAN 502 is any Wide Area Network (for example, the internet) capable of communicating computer data over non-local distances by any technology for communicating computer data, now known or to be developed in the future. In some aspects, the WAN 502 ay be replaced and/or supplemented by local area networks (LANs) designed to communicate data between devices located in a local area, such as a Wi-Fi network. The WAN 502 and/or LANs typically include computer hardware such as copper transmission cables, optical transmission fibers, wireless transmission, routers, firewalls, switches, gateway computers and edge servers.

End user device (EUD) 503 is any computer system that is used and controlled by an end user (for example, a customer of an enterprise that operates computer 501), and may take any of the forms discussed above in connection with computer 501. EUD 503 typically receives helpful and useful data from the operations of computer 501. For example, in a hypothetical case where computer 501 is designed to provide a recommendation to an end user, this recommendation would typically be communicated from network module 515 of computer 501 through WAN 502 to EUD 503. In this way, EUD 503 can display, or otherwise present, the recommendation to an end user. In certain aspects, EUD 503 may be a client device, such as thin client, heavy client, mainframe computer, desktop computer and so on.

As defined herein, the term “client device” means a data processing system that requests shared services from a server, and with which a user directly interacts. Examples of a client device include, but are not limited to, a workstation, a desktop computer, a computer terminal, a mobile computer, a laptop computer, a netbook computer, a tablet computer, a smart phone, a personal digital assistant, a smart watch, smart glasses, a gaming device, a set-top box, a smart television and the like. Network infrastructure, such as routers, firewalls, switches, access points and the like, are not client devices as the term “client device” is defined herein. As defined herein, the term “user” means a person (i.e., a human being).

Remote server 504 is any computer system that serves at least some data and/or functionality to computer 501. Remote server 504 may be controlled and used by the same entity that operates computer 501. Remote server 504 represents the machine(s) that collect and store helpful and useful data for use by other computers, such as computer 501. For example, in a hypothetical case where computer 501 is designed and programmed to provide a recommendation based on historical data, then this historical data may be provided to computer 501 from remote database 530 of remote server 504. As defined herein, the term “server” means a data processing system configured to share services with one or more other data processing systems.

Public cloud 505 is any computer system available for use by multiple entities that provides on-demand availability of computer system resources and/or other computer capabilities. especially data storage (cloud storage) and computing power, without direct active management by the user. Cloud computing typically leverages sharing of resources to achieve coherence and economies of scale. The direct and active management of the computing resources of public cloud 505 is performed by the computer hardware and/or software of cloud orchestration module 541. The computing resources provided by public cloud 505 are typically implemented by virtual computing environments that run on various computers making up the computers of host physical machine set 542, which is the universe of physical computers in and/or available to public cloud 505. The virtual computing environments (VCEs) typically take the form of virtual machines from virtual machine set 543 and/or containers from container set 544. It is understood that these VCEs may be stored as images and may be transferred among and between the various physical machine hosts, either as images or after instantiation of the VCE. Cloud orchestration module 541 manages the transfer and storage of images, deploys new instantiations of VCEs and manages active instantiations of VCE deployments. Gateway 540 is the collection of computer software, hardware, and firmware that allows public cloud 505 to communicate through WAN 502.

VCEs can be stored as “images,” and a new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 506 is similar to public cloud 505, except that the computing resources are only available for use by a single enterprise. While private cloud 506 is depicted as being in communication with WAN 502, in other aspects, a private cloud 506 may be disconnected from the internet entirely (e.g., WAN 502) and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this aspect, public cloud 505 and private cloud 506 are both part of a larger hybrid cloud.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

As another example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions. Each block in the flowchart or block diagrams may represent a module, segment, or portion of instructions, which comprises one or more executable instructions for implementing the specified logical function(s).

The terminology used herein is for the purpose of describing particular embodiments only and is not intended to be limiting of the invention. As used herein, the singular forms “a,” “an,” and “the” are intended to include the plural forms as well, unless the context clearly indicates otherwise. It will be further understood that the terms “includes,” “including,” “comprises,” and/or “comprising,” when used in this disclosure, specify the presence of stated features, integers, steps, operations, elements, and/or components, but do not preclude the presence or addition of one or more other features, integers, steps, operations, elements, components, and/or groups thereof.

Reference throughout this disclosure to “one embodiment,” “an embodiment,” “one arrangement,” “an arrangement,” “one aspect,” “an aspect,” or similar language means that a particular feature, structure, or characteristic described in connection with the embodiment is included in at least one embodiment described within this disclosure. Thus, appearances of the phrases “one embodiment,” “an embodiment,” “one arrangement,” “an arrangement,” “one aspect,” “an aspect,” and similar language throughout this disclosure may, but do not necessarily, all refer to the same embodiment.

The term “plurality,” as used herein, is defined as two or more than two. The term “another,” as used herein, is defined as at least a second or more. The term “coupled,” as used herein, is defined as connected, whether directly without any intervening elements or indirectly with one or more intervening elements, unless otherwise indicated. Two elements also can be coupled mechanically, electrically, or communicatively linked through a communication channel, pathway, network, or system. The term “and/or” as used herein refers to and encompasses any and all possible combinations of one or more of the associated listed items. It will also be understood that, although the terms first, second, etc. may be used herein to describe various elements, these elements should not be limited by these terms, as these terms are only used to distinguish one element from another unless stated otherwise or the context indicates otherwise.

The term “if” may be construed to mean “when” or “upon” or “in response to determining” or “in response to detecting,” depending on the context. Similarly, the phrase “if it is determined” or “if [a stated condition or event] is detected” may be construed to mean “upon determining” or “in response to determining” or “upon detecting [the stated condition or event]” or “in response to detecting [the stated condition or event],” depending on the context. As used herein, the terms “if,” “when,” “upon,” “in response to,” and the like are not to be construed as indicating a particular operation is optional. Rather, use of these terms indicate that a particular operation is conditional. For example and by way of a hypothetical, the language of “performing operation A upon B” does not indicate that operation A is optional. Rather, this language indicates that operation A is conditioned upon B occurring.

The foregoing description is just an example of embodiments of the invention, and variations and substitutions. While the disclosure concludes with claims defining novel features, it is believed that the various features described herein will be better understood from a consideration of the description in conjunction with the drawings. The process(es), machine(s), manufacture(s) and any variations thereof described within this disclosure are provided for purposes of illustration. Any specific structural and functional details described are not to be interpreted as limiting, but merely as a basis for the claims and as a representative basis for teaching one skilled in the art to variously employ the features described in virtually any appropriately detailed structure. Further, the terms and phrases used within this disclosure are not intended to be limiting, but rather to provide an understandable description of the features described.

What is claimed is:

1. A method of generating a policy for design of quantum devices using a quantum hardware design kit including instructions and parameters associated with the instructions, comprising:
defining an environment for a reinforcement learning architecture that includes a neural network as at least part of an agent; and
generating the policy by training the neural network using the environment, wherein
the defining the environment includes:
defining actions of the neural network from a set of the instructions and parameters combinations associated with the quantum hardware design kit; and
defining a reward function for generation of the policy.

2. The method of claim 1, wherein
the defining the environment includes receiving quantum device architecture, and
the reward function is configured to optimize the parameters for the quantum device architecture.

3. The method of claim 1, wherein
the reward function is configured to reward completion of a design of a quantum device.

4. The method of claim 1, wherein
the reward function is changed during the generating the policy.

5. The method of claim 1, wherein
the environment includes, separate from the quantum hardware design kit, a third-party library of predefined quantum components.

6. The method of claim 1, wherein
the defining the environment includes defining physical constraints of a quantum device.

7. The method of claim 1, wherein
a second neural network is configured to generate values associated with the reward function.

8. A computer hardware system for generating a policy for design of quantum devices using a quantum hardware design kit including instructions and parameters associated with the instructions, comprising:
a hardware processor configured to perform the following executable operations:
defining an environment for a reinforcement learning architecture that includes a neural network as at least part of an agent; and
generating the policy by training the neural network using the environment, wherein
the defining the environment includes:
defining actions of the neural network from a set of the instructions and parameters combinations associated with the quantum hardware design kit; and
defining a reward function for generation of the policy.

9. The system of claim 8, wherein
the defining the environment includes receiving quantum device architecture, and
the reward function is configured to optimize the parameters for the quantum device architecture.

10. The system of claim 8, wherein
the reward function is configured to reward completion of a design of a quantum device.

11. The system of claim 8, wherein
the reward function is changed during the generating the policy.

12. The system of claim 8, wherein
the environment includes, separate from the quantum hardware design kit, a third-party library of predefined quantum components.

13. The system of claim 8, wherein
the defining the environment includes defining physical constraints of a quantum device.

14. The system of claim 8, wherein
a second neural network is configured to generate values associated with the reward function.

15. A computer program product, comprising:
a computer readable storage medium having stored therein program code for generating a policy for design of quantum devices using a quantum hardware design kit including instructions and parameters associated with the instructions,
the program code, which when executed by a computer hardware system, cause the computer hardware system to perform:
defining an environment for a reinforcement learning architecture that includes a neural network as at least part of an agent; and
generating the policy by training the neural network using the environment, wherein
the defining the environment includes:
defining actions of the neural network from a set of the instructions and parameters combinations associated with the quantum hardware design kit; and
defining a reward function for generation of the policy.

16. The computer program product of claim 15, wherein
the defining the environment includes receiving quantum device architecture, and
the reward function is configured to optimize the parameters for the quantum device architecture.

17. The computer program product of claim 15, wherein
the reward function is configured to reward completion of a design of a quantum device.

18. The computer program product of claim 15, wherein
the reward function is changed during the generating the policy.

19. The computer program product of claim 15, wherein
the environment includes, separate from the quantum hardware design kit, a third-party library of predefined quantum components.

20. The computer program product of claim 15, wherein
the defining the environment includes defining physical constraints of a quantum device.
